(19) United States
(12) Patent Application Publication
(10) Pub. No.: US 2016/0016845 A1
(43) Pub. Date: Jan. 21, 2016

(54) COVER GLASS AND METHOD FOR MANUFACTURING SAME

(71) Applicant: CRUCIALTEC CO., LTD., Chungcheongnam-do (KR)

(72) Inventors: Hyung Sik Cho, Gyeonggi-do (KR); Yong Hyun Ji, Gyeonggi-do (KR)

(21) Appl. No.: 14/773,620

(22) PCT Filed: Nov. 29, 2013
(86) PCT No.: PCT/KR2013/011028

§ 371 Date: Sep. 8, 2015

(30) Foreign Application Priority Data
Mar. 5, 2013 (KR) 10-2013-0023574

(51) Int. Cl. C03C 15/00; G03F 7/32; C03C 17/34; G03F 7/20

(52) U.S. Cl. CPC C03C 15/00; G03F 7/20; G03F 7/32; C03C 17/3417; C03C 2217/73

(57) ABSTRACT

An embodiment of the present invention provides a cover glass which is slim and gives a better aesthetic feeling, and a method for manufacturing the same. The cover glass according to an embodiment of the present invention comprises: a glass substrate; a pattern portion formed on the glass substrate by etching; and a multi-layered thin film coated on the surface of the pattern portion.

### TECHNICAL FIELD

The present invention relates to a cover glass and a method for manufacturing the same, and more particularly, to a cover glass for portable terminals, which gets slim and gives a better aesthetic feeling, and a method for manufacturing the same.

### BACKGROUND ART

In recent years, there are increasing demands for slimness and design of portable terminals, such as mobile phones, smart phones, personal digital assistants (PDAs), portable multimedia players (PMPs), notebook computers, and the like, from consumers.

Thus, there have been various attempts to add design to a main window arranged at the outermost surface of a touch screen, in addition to the slimness of a display panel.

By way of example, design is added to a bezel area of a main window on which black ink is generally printed to hide wires of the display panel. In this case, films having hairline or geometric patterns are mainly laminated to apply black or white printing to the bezel area or add more luxurious design to the bezel area.

However, such a method is easily applied when an acrylic or PC sheet is used as a material for main windows, but is not easily applied as glass is preferred as the material for main windows. That is, the method has very limited applications since sufficient adhesion between glass and a UV pattern is not secured.

FIG. 1 is an exemplary view showing a configuration of a conventional cover glass.

As shown in FIG. 1, the conventional cover glass 10 includes a polyethylene terephthalate (hereinafter referred to as “PET”) film 40 adhered to a lower surface of a glass substrate 20 by an optically clear adhesive (hereinafter referred to as “OCA”) 30. Also, an ultraviolet (UV) pattern 50 is applied onto the PET film 40. The UV pattern 50 is coated with a layer 60 configured to adjust the wavelengths of light so as to realize colors, and a black matrix layer 70 is formed on the layer 60.

As described above, since the PET film 40, and the OCA 30 configured to adhere the PET film 40 to the glass substrate 20 are further provided, and the UV pattern 50 is formed on the PET film 40, the conventional cover glass 10 has a problem in that it is difficult to get slim.

Also, since light emitted from the display panel goes through the PET film 40 and the OCA 30, the conventional cover glass 10 has a problem in that its transmissivity may be degraded.

Meanwhile, since the UV pattern 50 is provided on the PET film 40, that is, since the UV pattern 50 is formed in an embossed shape, an average vertical distance L1 when light incident from the outside reaches the layer 60, and an average vertical distance L1 when the light is reflected on the layer 60 and emitted outward the glass substrate 20 get longer. Accordingly, the light loss may occur during a process in which light is incident, reflected on, and emitted from the layer 60. Also, since the light incident on the layer 60, and the light reflected on and emitted from the layer 60 go through the OCA 30 and the PET film 40, the transmissivity may also be degraded. Such outcomes may interfere with providing clear colors, and result in the loss of aesthetic feeling.

### DISCLOSURE

### Technical Problem

The present invention is designed to solve the problems of the prior art, and therefore it is an object of the present invention to provide a cover glass which gets slim and gives a better aesthetic feeling, and a method for manufacturing the same.

### Technical Solution

To the problems of the prior art, according to an aspect of the present invention, there is provided a cover glass which includes a glass substrate, a pattern portion formed in the glass substrate by etching, and a multi-layered thin film coated on a surface of the pattern portion.

According to an exemplary embodiment of the present invention, the surface of the pattern portion may be formed as an inner surface of the glass substrate.

According to an exemplary embodiment of the present invention, the pattern portion may be formed in a bezel area of the glass substrate.

According to an exemplary embodiment of the present invention, the cover glass may further include a print unit formed to cover the multi-layered thin film.

To the problems of the prior art, according to another aspect of the present invention, there is provided a method for manufacturing a cover glass, which includes masking a glass substrate with an acid-resistant photoresist ink, and etching the glass substrate with a non-hydrofluoric acid-based etchant to form a pattern portion.

According to an exemplary embodiment of the present invention, the etching in the etching of the glass substrate with the non-hydrofluoric acid-based etchant to form the pattern portion may be performed in a bezel area of the glass substrate.

According to an exemplary embodiment of the present invention, the masking of the glass substrate with the acid-resistant photoresist ink may include applying the acid-resistant photoresist ink onto the glass substrate to a thickness of 10 to 20 μm, arranging a mask pattern on a top surface of a resist film to which the acid-resistant photoresist ink is applied, and exposing the mask pattern, and developing the exposed pattern formed in the resist film.

According to an exemplary embodiment of the present invention, the etching in the etching of the glass substrate with the non-hydrofluoric acid-based etchant to form the pattern portion may be performed by finely bubbling the non-hydrofluoric acid-based etchant.

According to an exemplary embodiment of the present invention, the non-hydrofluoric acid-based etchant may include 50 to 300 g/L of ammonium fluoride, 1 to 30 g/L of an amine-based compound, 0.1 to 5 g/L of an anionic surfactant, and water.

According to an exemplary embodiment of the present invention, the amine-based compound may include at least one selected from the group consisting of monoethylamine, diethylamine, and triethylamine.

According to an exemplary embodiment of the present invention, the anionic surfactant may include alkylbenzene sulfonate or sodium lauryl sulfate.

To the problems of the prior art, according to still another aspect of the present invention, there is provided a method for manufacturing a cover glass, which includes masking a glass substrate, etching the glass substrate to form a pattern portion, and coating the pattern portion with a multi-layered thin film.

According to an exemplary embodiment of the present invention, the masking of the glass substrate may be performed using an acid-resistant photoresist ink, and the etching of the glass substrate to form the pattern portion may be performed using a non-hydrofluoric acid-based etchant.

According to an exemplary embodiment of the present invention, the masking of the glass substrate may include applying the acid-resistant photoresist ink to the glass substrate to a thickness of 10 to 20 μm, arranging a mask pattern on a top surface of a resist film to which the acid-resistant photoresist ink is applied, and exposing the mask pattern, and developing the exposed pattern formed in the resist film.

According to an exemplary embodiment of the present invention, the etching in the etching of the glass substrate to form the pattern portion may be performed by finely bubbling the non-hydrofluoric acid-based etchant.

According to an exemplary embodiment of the present invention, the non-hydrofluoric acid-based etchant may include 50 to 300 g/L of ammonium fluoride, 1 to 30 g/L of an amine-based compound, 0.1 to 5 g/L of an anionic surfactant, and water.

According to an exemplary embodiment of the present invention, the amine-based compound may include at least one selected from the group consisting of monoethylamine, diethylamine, and triethylamine.

According to an exemplary embodiment of the present invention, the anionic surfactant may include alkylbenzene sulfonate or sodium lauryl sulfate.

According to an exemplary embodiment of the present invention, the multi-layered thin film may be formed by stacking at least one selected from the group consisting of a titanium oxide layer, and a silicon oxide layer.

According to an exemplary embodiment of the present invention, the etching in the etching of the glass substrate to form the pattern portion may be performed in a bezel area of the glass substrate.

According to an exemplary embodiment of the present invention, after the etching of the glass substrate to form the pattern portion, a fingerprint-resistant/anti-reflective thin film coating layer may be further formed to a thickness of 1,500 to 8,000 Å on a rear surface of the glass substrate on which the pattern portion is formed.

According to an exemplary embodiment of the present invention, the method may further include forming a print unit to cover the multi-layered thin film after the coating of the pattern portion with the multi-layered thin film.

### Advantageous Effects

According to an exemplary embodiment of the present invention, since a pattern portion is directly formed on a glass substrate by etching the glass substrate, the configurations of an OCA, a PET film and a UV pattern are not required, unlike the prior art, thereby reducing the entire thickness of the cover glass and improving transmissivity as well.

Also, according to an exemplary embodiment of the present invention, since the pattern portion is formed inward the glass substrate so that a distance from a multi-layered thin film to the outermost surface of the glass substrate gets shorter, the light loss in the glass substrate can be reduced. As a result, more clear and beautiful colors may be provided, thereby improving an aesthetic feeling.

In addition, according to an exemplary embodiment of the present invention, pattern precision of a resist film can be enhanced since the glass substrate is masked with an acid-resistant photoresist ink, and a duration time of a pattern shape of the resist film upon etching can increase as an etching process is performed using a non-hydrofluoric acid-based etchant. Also, fine patterns can be formed by adjusting an etching rate so that the glass substrate is not etched too rapidly.

Further, according to an exemplary embodiment of the present invention, since the pattern portion is directly formed in the glass substrate, phenomena such as invasion and delamination which have occurred in the conventional cover glass can be fundamentally prevented, thereby improving durability.

It should be appreciated that the advantageous effects of the present invention are not limited to the effects described above, but encompass all effects that can be derived from the configurations of the present invention disclosed in the detailed description of the invention or the appended claims.

### DESCRIPTION OF DRAWINGS

FIG. 1 is an exemplary view showing a configuration of a conventional cover glass.

FIG. 2 is an exemplary plan view showing a cover glass according to an exemplary embodiment of the present invention.

FIG. 3 is an exemplary cross-sectional view showing the cover glass according to an exemplary embodiment of the present invention.

FIG. 4 is an exemplary flowchart showing a method for manufacturing a cover glass according to an exemplary embodiment of the present invention.

FIG. 5 is an exemplary flowchart showing a masking process of the method for manufacturing a cover glass according to an exemplary embodiment of the present invention.

### BRIEF DESCRIPTION OF MAIN PARTS IN THE DRAWINGS

10,100: cover glass
20,110: glass substrate
120: pattern portion
130: multi-layered thin film
150: print unit
170: thin film coating layer

### BEST MODE

Hereinafter, preferred embodiments of the present invention will be described in detail referring to the accompanying drawings. However, the present invention can be implemented in several different forms, and thus is not limited to the embodiments described herein. In order to describe embodiments of the present invention with greater clarity, certain parts have been omitted in the drawings, and like parts are used to have like reference numerals throughout the specification.

In the specification, the description that a part is “connected” to another part refers not only to those cases in which the parts are “connected directly” but also to those cases in which the parts are “connected indirectly” by way of one or more other members interposed therebetween. Also, the description that a part “includes” a component means that additional components may further be included and does not preclude the existence of other components unless specifically indicated.

Certain embodiments of the present invention will now be described in more detail with reference to the accompanying drawings. According to an exemplary embodiment of the present invention, a cover glass of a smart phone will be described by way of example for the sake of convenience of description.

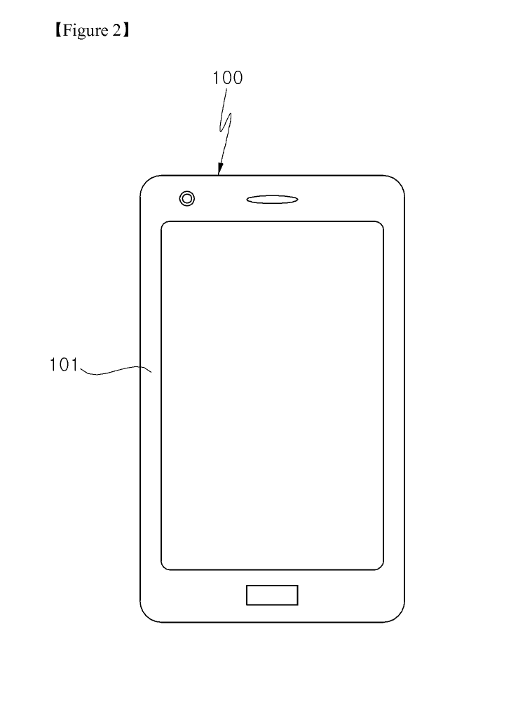

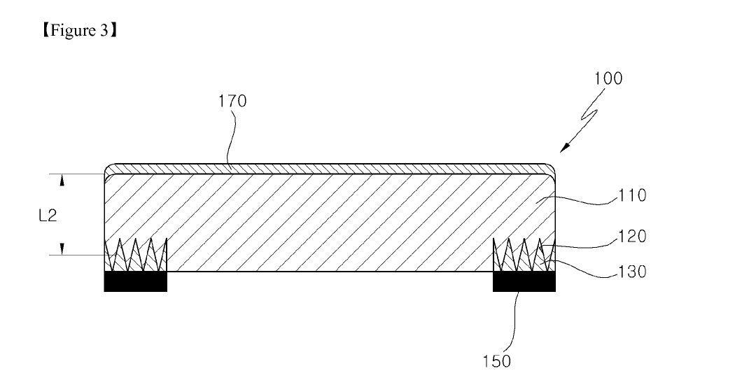

FIG. 2 is an exemplary plan view showing a cover glass according to an exemplary embodiment of the present invention, and FIG. 3 is an exemplary cross-sectional view showing the cover glass according to an exemplary embodiment of the present invention.

As shown in FIGS. 2 and 3, the cover glass 100 glass according to an exemplary embodiment of the present invention includes a glass substrate 110, a pattern portion 120, and a multi-layered thin film 130.

The glass substrate 110 protects a display panel inside a portable terminal, and a screen of the display panel is seen through the glass substrate 110. Wires (not shown) of the display panel, a speaker (not shown), a camera (not shown), and the like may be disposed in a bezel area 101 that is an edge of the glass substrate 110. The glass substrate 110 may be cut into pieces of a certain size according to a purpose of use, and a surface of the glass substrate 110 may be washed and dried. The glass substrate 110 may be a soda-lime glass substrate, an alkali-free glass substrate, or a tempered glass substrate.

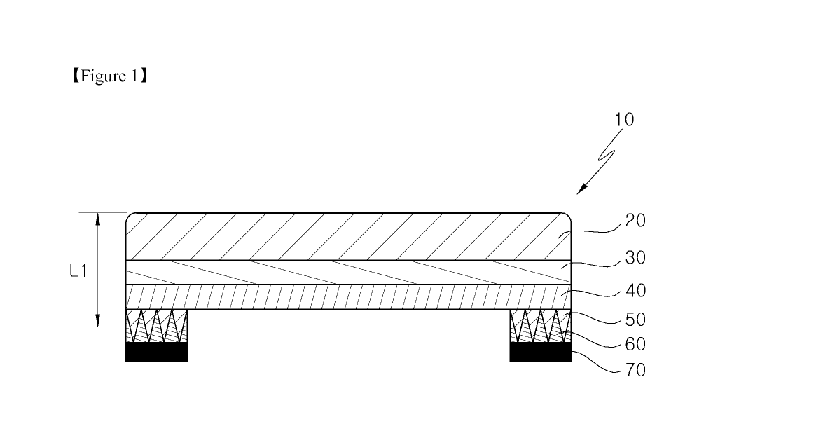

The pattern portion 120 may be formed in the glass substrate 110 by etching. In this case, the pattern portion 120 may be formed in the bezel area 101. That is, a surface of the pattern portion 120 is formed as an inner surface of the glass substrate 110. Therefore, unlike the conventional cover glass, light incident on the glass substrate 110 may directly reach a surface of the pattern portion 120 without passing through components made of different materials (an OCA 30 (see FIG. 1), a PET film 40 (see FIG. 1), and a UV pattern 50 (see FIG. 1) provided in a conventional cover glass 10 (see FIG. 1)). That is, the cover glass 100 may have a distance at which the light reaches the pattern portion 120 gets shorter, and show higher transmissivity, compared to the conventional cover glass 10.

The pattern portion 120 may be formed in various shapes and depths. The pattern portion 120 may be in the form of lines, figures, and the like. Such pattern shapes may be repeatedly formed to give geometric patterns such as hairline or weave patterns. In addition, the pattern portion 120 may include shapes of symbols, numbers, letters, and the like. In this case, the pattern portion 120 may be formed with different depth according to the shapes.

The multi-layered thin film 130 may be coated on a surface of the pattern portion 120. The multi-layered thin film 130 may be formed by stacking at least one of a metal oxide layer and a non-metal oxide layer. The multi-layered thin film 130 may widely adjust wavelengths of light incident on the pattern portion 120. Therefore, various colors may be realized on the glass substrate 110. By way of example, the multi-layered thin film 130 may include a titanium oxide layer and a silicon oxide layer. In this case, the multi-layered thin film 130 may be formed by stacking at least one of the titanium oxide layer and the silicon oxide layer.

A print unit 150 may be formed above the multi-layered thin film 130. The print unit 150 may be formed to cover the multi-layered thin film 130. The print unit 150 blocks light emitted from the display panel to display colors on the display panel through only a central region of the glass substrate 110, and reflects external incident light.

Therefore, when the external incident light is reflected on the print unit 150, the incident light is scattered or reflected on a surface shape of the pattern portion 120 and the multi-layered thin film 130 to give various colorful stereoscopic effects.

In particular, in the cover glass 100 according to an exemplary embodiment of the present invention, since a surface of the pattern portion 120 is formed as an inner surface of the glass substrate 110, that is, since the pattern portion 120 is formed inward the glass substrate 110, an average vertical distance L2 at which light incident from the outside reaches the multi-layered thin film 130 may get shorter. That is, the average vertical distance L2 at which light incident from the outside reaches the multi-layered thin film 130 in the cover glass 100 according to an exemplary embodiment of the present invention may be much shorter than the average vertical distance L1 (see FIG. 1) at which light incident from the outside reaches the layer 60 (see FIG. 1) in the conventional cover glass 10. This indicates that the distance at which the light reflected on the multi-layered thin film 130 is emitted outward the glass substrate 110 gets shorter. As described above, when the pattern portion 120 according to an exemplary embodiment of the present invention is formed in a geometric pattern such as a hairline or weave pattern, the light reflected on the multi-layered thin film 130 may be emitted at various angles. In this case, since the distance from the multi-layered thin film 130 to the outermost surface of the glass substrate 110 is short, the light loss in the glass substrate 110 may be reduced. As a result, an effect of improving an aesthetic feeling may be provided since more clear and beautiful colors may be provided. A case in which the pattern portion 120 is filled with the multi-layered thin film 130 is shown in FIG. 3, for the sake of convenience. However, the multi-layered thin film 130 may be deposited to a very thin thickness, and thus may be formed on a surface of the pattern portion 120 along the curve of the pattern portion 120.

A fingerprint-resistant/anti-reflective thin film coating layer 170 may be further formed at a rear surface of the glass substrate 110 on which the pattern portion 120 is formed. The thin film coating layer 170 may be formed to a thickness of 1,500 to 8,000 Å. The thin film coating layer 170 controls the reflection of light to make patterns clearer, thereby realizing more luxurious images. The thin film coating layer 170 may be coated using a microdroplet spray method.

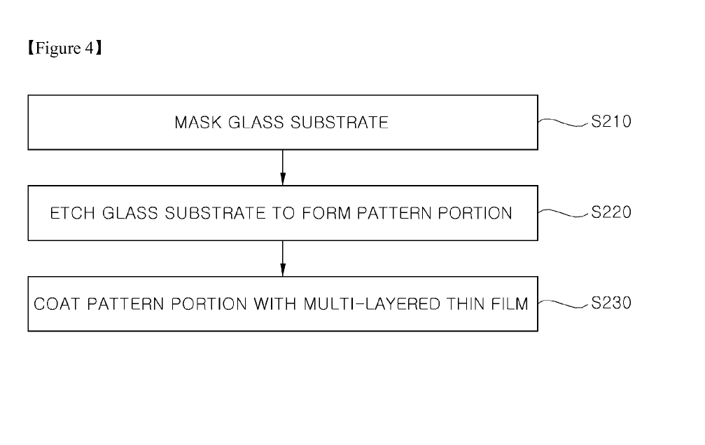

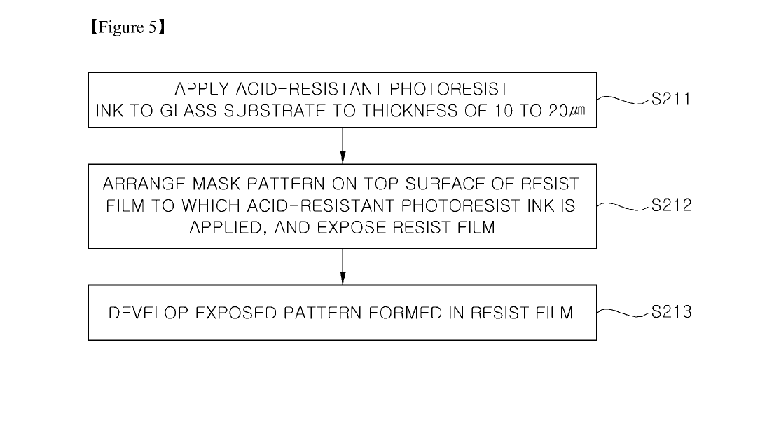

Next, a method for manufacturing a cover glass according to an exemplary embodiment of the present invention will be described with reference to FIGS. 4 and 5. FIG. 4 is an exemplary flowchart showing a method for manufacturing a cover glass according to an exemplary embodiment of the present invention, and FIG. 5 is an exemplary flowchart showing a masking process of the method for manufacturing a cover glass according to an exemplary embodiment of the present invention.

As shown in FIGS. 4 and 5, the method for manufacturing a cover glass according to an exemplary embodiment of the present invention includes masking a glass substrate (S210). Also, the masking of the glass substrate (S210) may include applying an acid-resistant photoresist ink to a glass substrate to a thickness of 10 to 20 μm (S211).

The acid-resistant photoresist ink may not react with an etchant for etching a glass. Since the acid-resistant photoresist ink shows etching resistance, and withstands strong acids and hydrofluoric acid (HF) for a long period of time, it is advantageous to form a fine pattern.

The acid-resistant photoresist ink may further include at least one resin component selected from the group consisting of an epoxy-based resin, a silicon-based resin, an acrylic resin, and a urethane-based resin. In this case, a hardener or paint may be further included. When the hardener is added at a large amount, the acid-resistant photoresist ink may be hardened rapidly, and thus may not be formed in a proper position. On the other hand, when the hardener is added at a small amount, the acid-resistant photoresist ink may be hardened too slowly. Accordingly, the hardener may be included at a proper ratio so that desired patterns are not formed in an oversized scale. The acid-resistant photoresist ink may have sufficient adhesion to the glass substrate 110.

The acid-resistant photoresist ink may be coated on the glass substrate 110 to a certain thickness using methods such as screen printing, spin coating, painting, spraying, dip coating, feeding, and slit die coating.

Also, the masking of the glass substrate (S210) may include arranging a mask pattern on a top surface of a resist film to which the acid-resistant photoresist ink is applied, and exposing the mask pattern (S212), and developing the exposed pattern formed in the resist film (S213). In the exposure process (S212), light irradiated to the mask pattern may be UV light. In the development process (S213), a solution of 2 to 7% sodium carbonate having a temperature of 45 to 60° C. may be used as a developing solution. In this case, the resist film is immersed in the developing solution for 60 to 180 seconds, washed, and then dried to form a fine pattern on the resist film.

The acid-resistant photoresist ink may be a positive type in which the photoresist ink becomes soluble upon exposure, or a negative type in which the photoresist ink becomes insoluble upon exposure.

Next, the etching of the glass substrate to form the pattern portion (S220) may be performed. Also, an etchant used to etch the glass substrate may be a non-hydrofluoric acid-based etchant. The non-hydrofluoric acid-based etchant may include 50 to 300 g/L of ammonium fluoride (NH₄F), 1 to 30 g/L of an amine-based compound, 0.1 to 5 g/L of an anionic surfactant, and water. The water may be a solvent. Such a non-hydrofluoric acid-based etchant may control a rapid reaction of glass with hydrofluoric acid, and may also inhibit surface adsorption of generated silicofluorides to enhance permeability of a solution, thereby realizing fine patterns rapidly. When a conventional hydrofluoric acid etching agent or etchant is pure hydrofluoric acid (HF), the glass substrate may be etched too rapidly, which makes it difficult to form fine patterns. As a result, the fine patterns may be formed more effectively when the non-hydrofluoric acid-based etchant is used as described above. That is, the pattern precision may be enhanced without causing damage to the pattern of the resist film by masking the glass substrate with the acid-resistant photoresist ink and performing an etching process using the non-hydrofluoric acid-based etchant. Also, a duration time of a pattern shape of the resist film upon etching may increase, and the fine patterns can be formed by adjusting an etching rate so that the glass substrate is not etched too rapidly. The amine-based compound may include at least one selected from the group consisting of monoethylamine (MEA), diethylamine (DEA), and triethylamine (TEA). Such an amine-based compound may control a reaction rate of glass with an etchant.

The anionic surfactant may include alkylbenzene sulfonate or sodium lauryl sulfate. Such an anionic surfactant may be used for permeability and cleanability of the etchant.

In this process (S220), the etching may be performed by finely bubbling the non-hydrofluoric acid-based etchant. When the etchant is finely bubbled, a physical force may be uniformly applied to the etchant, and thus rapid etching and cleaning may be efficiently performed. In this process (S220), the pattern portion formed in the glass substrate by etching may be etched to have a depth of 10 to 30 μm. For this purpose, a microbubble system may be used in this process (S220).

TABLE 1

| | | Comparative | |
|---|---|---|---|
| Comparison item | Example 1 | Example 1 | Note |
| Etching rate | 5 to 10 | 20 to 30 | Comparison at |
| (μm/min) | | | room temperature |
| Etching resistance | Not peeled off | Slightly | |
| of resist film | | peeled off | |

Table 1 shows the experimental results obtained by comparing the etching rates of the non-hydrofluoric acid-based etchant used in the method for manufacturing a cover glass according to an exemplary embodiment of the present invention, and the conventional glass etchant, and the peelability of the resist films. The same resist films patterned through various processes were used as the resist films used in Example 1 and Comparative Example 1, and the non-hydrofluoric acid-based etchant according to an exemplary embodiment of the present invention and the conventional glass etching agent formed of a conventional composition including hydrofluoric acid, an inorganic acid, and an additive were used as the etchants.

Specifically, the non-hydrofluoric acid-based etchant used in Example 1 was prepared by dissolving 50 to 300 g/L of ammonium fluoride, 1 to 30 g/L of an amine-based compound, and 0.1 to 5 g/L of an anionic surfactant in 1 L of water. The conventional hydrofluoric acid-based etchant used in Comparative Example 1 includes 50 to 350 g/L of hydrofluoric acid (HF), 100 to 200 g/L of an inorganic acid (sulfuric acid, hydrochloric acid, etc.), and water. As listed in Table 1, in Example 1, the etching rate was 5 to 10 μm/min, which was slower than the etching rate (20 to 30 μm/min) in Comparative Example 1. Also, the resist film was not peeled off in Example 1, but some of the resist film was peeled off in Comparative Example 1. That is, when the non-hydrofluoric acid-based etchant according to an exemplary embodiment of the present invention is used, the non-hydrofluoric acid-based etchant has a slower etching rate than the conventional hydrofluoric acid-based etchant, resulting in ease in formation of the fine patterns. Upon etching, the fine patterns may be formed in the glass substrate without causing damage to the pattern of the resist film.

TABLE 2

| Comparison item | Example 2 | Comparative Example 2 |
|---|---|---|
| Fine pattern distance | 30 to 80 μm | 100 μm or more |
| Boundary of etching | Not peeled off at | Partially peeled off at |
| region | boundary region | boundary region after |
| | after etching | etching |

Table 2 shows the etching resistance of the pattern when the resist film masked with the acid-resistant photoresist ink used in the method for manufacturing a cover glass according to an exemplary embodiment of the present invention, and the resist film masked with the conventional mask ink were etched with the non-hydrofluoric acid-based etchant according to an exemplary embodiment of the present invention. The etching was performed at room temperature in Example 2 and Comparative Example 2, and fine bubbles were generated in the etchant. In this case, the etching time was 2 to 5 minutes. As a result, it was revealed that the fine patterns were effectively realized as a boundary surface of the resist film masked with the acid-resistant photoresist ink and a boundary surface of the resist film etched in the glass substrate are clearly viewed in Example 2. In this case, the distance between the fine patterns formed in the glass substrate was 30 to 80 μm.

However, it was revealed that the resist film masked with the conventional mask ink was peeled off, and thus the patterns etched in the glass substrate were stained, and a reaction product, that is, slurry, was formed between the resist film and the glass substrate, and white powder stuck between the resist film and the glass substrate was observed. The distance between the fine patterns formed in the glass substrate was 100 μm or more. That is, when the glass substrate was masked with the acid-resistant photoresist ink according to an exemplary embodiment of the present invention, and etched with the non-hydrofluoric acid-based etchant, the boundary and surface of the patterns etched in the glass substrate were cleaner than those of the patterns etched in the glass substrate masked with the conventional mask ink, and the distance between the patterns was able to be narrowed, which makes it possible to form fine patterns.

After the etching, pure water may be sprayed at a pressure of 1.0 to 2.0 kg/cm² to perform a washing process of removing the etchant remaining in the glass substrate.

After the etchant is removed, the resist film remaining in a surface of the glass substrate is removed. The removal of the resist film is performed as follows. The resist film is immersed in a solution of 3 to 10% sodium hydroxide at a constant temperature to be separated, and then washed with pure water.

The etching in this process (S220) may be performed in a bezel area of the glass substrate 110. Therefore, the pattern portion formed through this process (S220) may be formed in the bezel area.

The pattern portion may be in the form of lines, figures, and the like. Such pattern shapes may be repeatedly formed to give geometric patterns such as hairline or weave patterns. Since the pattern portion formed thus has a higher level of stereoscopic effect and change than the pattern obtained by conventional printing or by laminating films, a superior ornament effect may be realized, and a better aesthetic feeling maybe given. In addition, the pattern portion may include logos such as symbols, numbers, letters, etc. In this case, the pattern portion may be formed with different depths according to the type of the pattern portions, for example, geometric patterns and logos.

As described above, according to an exemplary embodiment of the present invention, since the pattern portion is directly formed in the glass substrate by etching the glass substrate, the configurations of an OCA, a PET film and a UV pattern are not required, unlike the prior art, thereby reducing the entire thickness of the cover glass and improving transmissivity as well.

Also, since the pattern portion is directly formed in the glass substrate, phenomena such as invasion and delamination which have occurred in the conventional cover glass may be fundamentally prevented, thereby improving durability.

As the next process, a process of coating the pattern portion with a multi-layered thin film (S230) may be performed. The multi-layered thin film may be formed on a surface of the pattern portion. Therefore, the multi-layered thin film may be arranged inside the glass substrate. The multi-layered thin film may be formed by stacking at least one of a metal oxide layer and a non-metal oxide layer. The metal oxide layer may be a titanium oxide layer, and the non-metal oxide layer may be a silicon oxide layer. The multi-layered thin film may widely control wavelengths of light incident on the pattern portion, thereby realizing various colors on the glass substrate.

Also, after the coating of the pattern portion with the multi-layered thin film (S230), a process of forming a print unit to cover the multi-layered thin film may be further performed. The forming of the print unit may be performed in a bezel area, and the print unit may be formed to cover the multi-layered thin film formed in the bezel area. The print unit may be a black matrix layer printed with a black ink, and the black ink may include an inorganic compound such as a metal or a metal oxide, or an organic compound such as a polymer resin. The print unit blocks light emitted from the display panel to display colors on the display panel through only a central region of the glass substrate, and reflects external incident light.

Meanwhile, after the etching of the glass substrate with the etchant to form the pattern portion (S220), the fingerprint-resistant/anti-reflective thin film coating layer 170 may be further formed on a rear surface of the glass substrate 110, on which the pattern portion 120 is formed, to a thickness of 1,500 to 8,000 Å. The thin film coating layer 170 may control the reflection of light to make patterns clearer, thereby realizing more luxurious images. The thin film coating layer 170 may be coated using a microdroplet spray method.

Although the exemplary embodiments of the present invention presented herein have been disclosed for illustrative purposes, it should be understood to those skilled in the art to which the present invention pertains that various modifications and changes are possible without departing from the scope and spirit of the present invention. Therefore, the exemplary embodiments disclosed above are illustrative in all aspects, but not intended to limit the present invention. For example, respective components described in an integral form may be implemented in separate forms, and the components described in separate forms may also be implemented in an integral form.

Also, it should be understood that the scope of the present invention is defined by the appended claims, and all the modifications and modified forms derived from the spirit and scope of the appended claims and their equivalents are encompassed in the scope of the present invention.

1. A cover glass comprising:
a glass substrate;
a pattern portion formed in the glass substrate by etching; and
a multi-layered thin film coated on a surface of the pattern portion.

2. The cover glass of claim 1, wherein the surface of the pattern portion is formed as an inner surface of the glass substrate.

3. The cover glass of claim 1, wherein the pattern portion is formed in a bezel area of the glass substrate.

4. The cover glass of claim 1, further comprising a print unit formed to cover the multi-layered thin film.

5. A method for manufacturing a cover glass, comprising:
masking a glass substrate with an acid-resistant photoresist ink; and
etching the glass substrate with a non-hydrofluoric acid-based etchant to form a pattern portion.

6. The method of claim 5, wherein the etching in the etching of the glass substrate with the non-hydrofluoric acid-based etchant to form the pattern portion is performed in a bezel area of the glass substrate.

7. The method of claim 5, wherein the masking of the glass substrate with the acid-resistant photoresist ink comprises:
applying the acid-resistant photoresist ink onto the glass substrate to a thickness of 10 to 20 μm;
arranging a mask pattern on a top surface of a resist film to which the acid-resistant photoresist ink is applied, and exposing the mask pattern; and
developing the exposed pattern formed in the resist film.

8. The method of claim 5, wherein the etching in the etching of the glass substrate with the non-hydrofluoric acid-based etchant to form the pattern portion is performed by finely bubbling the non-hydrofluoric acid-based etchant.

9. The method of claim 5, wherein the non-hydrofluoric acid-based etchant comprises 50 to 300 g/L of ammonium fluoride, 1 to 30 g/L of an amine-based compound, 0.1 to 5 g/L of an anionic surfactant, and water.

10. The method of claim 9, wherein the amine-based compound comprises at least one selected from the group consisting of monoethylamine, diethylamine, and triethylamine.

11. The method of claim 9, wherein the anionic surfactant comprises alkylbenzene sulfonate or sodium lauryl sulfate.

12. A method for manufacturing a cover glass, comprising:
masking a glass substrate;
etching the glass substrate to form a pattern portion; and
coating the pattern portion with a multi-layered thin film.

13. The method of claim 12, wherein the masking of the glass substrate is performed using an acid-resistant photoresist ink, and the etching of the glass substrate to form the pattern portion is performed using a non-hydrofluoric acid-based etchant.

14. The method of claim 13, wherein the masking of the glass substrate comprises:
applying the acid-resistant photoresist ink to the glass substrate to a thickness of 10 to 20 μm;
arranging a mask pattern on a top surface of a resist film to which the acid-resistant photoresist ink is applied, and exposing the mask pattern; and
developing the exposed pattern formed in the resist film.

15. The method of claim 13, wherein the etching in the etching of the glass substrate to form the pattern portion is performed by finely bubbling the non-hydrofluoric acid-based etchant.

16. The method of claim 13, wherein the non-hydrofluoric acid-based etchant comprises 50 to 300 g/L of ammonium fluoride, 1 to 30 g/L of an amine-based compound, 0.1 to 5 g/L of an anionic surfactant, and water.

17. The method of claim 16, wherein the amine-based compound comprises at least one selected from the group consisting of monoethylamine, diethylamine, and triethylamine.

18. The method of claim 16, wherein the anionic surfactant comprises alkylbenzene sulfonate or sodium lauryl sulfate.

19. The method of claim 12, wherein the multi-layered thin film is formed by stacking at least one selected from the group consisting of a titanium oxide layer, and a silicon oxide layer.

20. The method of claim 12, wherein the etching in the etching of the glass substrate to form the pattern portion is performed in a bezel area of the glass substrate.

21. The method of claim 12, wherein, after the etching of the glass substrate to form the pattern portion, a fingerprint-resistant/anti-reflective thin film coating layer is further formed to a thickness of 1,500 to 8,000 Å on a rear surface of the glass substrate on which the pattern portion is formed.

22. The method of claim 12, further comprising, after the coating of the pattern portion with the multi-layered thin film:
forming a print unit to cover the multi-layered thin film.
